(19) United States
(12) Patent Application Publication
(10) Pub. No.: US 2012/0012150 A1
(43) Pub. Date: Jan. 19, 2012

(54) Photoelectric Conversion Module

(75) Inventors: Nam-Choul Yang, Yongin-si (KR); Jung-Suk Song, Yongin-si (KR); Jong-Ki Lee, Yongin-si (KR); Hyun-Chul Kim, Yongin-si (KR); Joo-Sik Jung, Yongin-si (KR); Suk-Beom You, Yongin-si (KR)

(73) Assignee: SAMSUNG SDI CO., LTD., Yongin-si (KR)

(21) Appl. No.: 13/017,164

(22) Filed: Jan. 31, 2011

(30) Foreign Application Priority Data
Jul. 19, 2010 (KR) 10-2010-0069605

(51) Int. Cl. H01L 31/05

(52) U.S. Cl. 136/244

(57) ABSTRACT

A photoelectric conversion module including an island type connecting member. A photoelectric conversion module includes: a first substrate and a second substrate, which are disposed to face each other; a sealing member disposed between the first and second substrates, and defining a plurality of photoelectric cells performing photoelectric conversion; and an island type connecting member connecting neighboring photoelectric cells from among the plurality of photoelectric cells.

### CLAIM OF PRIORITY

This application makes reference to, incorporates the same herein, and claims all benefits accruing under 35 U.S.C §119 from an application earlier filed in the Korean Industrial Property Office on Jul. 19, 2010, and there duly assigned Serial No. 10-2010-0069605 by that Office.

### BACKGROUND OF THE INVENTION

1. Field of the Invention

One or more embodiments of the present invention relate to a photoelectric conversion module.

2. Description of the Related Art

Photoelectric conversion devices convert light energy into electric energy and have been studied as an energy source for replacing fossil fuels, and solar cells using sunlight have come into the spotlight.

Various types of solar cells having various driving principles have been investigated. Silicon or crystalline solar cells have a wafer shape and include a p-n semiconductor junction, but the manufacturing costs thereof are high due to the characteristics of processes for forming and handling semiconductor materials having a high degree of purity.

Unlike silicon solar cells, dye-sensitized solar cells mainly include a photosensitive dye for generating excited electrons in response to visible light, a semiconductor material for receiving the excited electrons, and an electrolyte for reacting with the excited electrons in an external circuit. Dye-sensitized solar cells have high photoelectric conversion efficiency compared to the silicon solar cells, and thus are expected to be the next generation of solar cells.

A series connection structure of such dye-sensitized solar cells includes a Z type, a W type, a monolith type, or an in-plane type. Here, a conducting structure for connecting adjacent cells is required in the Z type, and thus a light receiving unit may be at a loss and a resistance may increase.

### SUMMARY OF THE INVENTION

One or more embodiments of the present invention include a photoelectric conversion module, wherein an aperture ratio and photoelectric conversion efficiency are increased by using an island type connecting member for connecting photoelectric cells.

Additional aspects will be set forth in part in the description which follows and, in part, will be apparent from the description, or may be learned by practice of the presented embodiments.

According to one or more embodiments of the present invention, a photoelectric conversion module includes: a first substrate and a second substrate, which are disposed to face each other; a sealing member disposed between the first and second substrates, and defining a plurality of photoelectric cells performing photoelectric conversion; and an island type connecting member connecting neighboring photoelectric cells from among the plurality of photoelectric cells.

Each of the plurality of photoelectric cells may include a first electrode and a second electrode having different polarities, and the island type connecting member may extend to contact the first electrode of any one of the neighboring photoelectric cells and the second electrode of the other one of the neighboring photoelectric cells.

At least one of the first and second electrodes may include a metal electrode having a stripe pattern.

A width of the stripe pattern of the metal electrode may be from about 5 mm to about 15 mm.

The sealing member may include: a cell divider dividing the plurality of photoelectric cells; and an accommodation hole accommodating the island type connecting member.

The accommodation hole may be formed to penetrate a partial area of the cell divider.

A thickness of the cell divider where the accommodation hole is not formed may be thinner than a thickness of the cell divider where the accommodation hole is formed.

The island connecting member may be disposed between the neighboring photoelectric cells.

A plurality of the island type connecting members may be disposed apart from each other.

The island type connecting member may include a metal or a conductive resin.

The plurality of photoelectric cells may extend along one side unit of the first and second substrates and may be disposed parallel to each other.

According to one or more embodiments of the present invention, a photoelectric conversion module includes: a plurality of photoelectric cells performing photoelectric conversion and disposed between a first substrate and a second substrate facing the first substrate; and at least one island type connecting member disposed between neighboring photoelectric cells from among the plurality of photoelectric cells and connecting the neighboring photoelectric cells.

Each of the plurality of photoelectric cells may include: a first electrode and a second electrode respectively formed on the first substrate and the second substrate; a semiconductor layer formed on the first electrode; and an electrolyte disposed between the semiconductor layer and the second electrode.

The at least one island type connecting member may extend to connect the first electrode of any one of the neighboring photoelectric cells and the second electrode of the other one of the neighboring photoelectric cells.

At least one of the first and second electrodes may include a metal electrode having a stripe pattern.

A width of the stripe pattern of the metal electrode may be from about 5 mm to about 15 mm.

The plurality of photoelectric cells may be defined by a sealing member including cell dividers that extend in one direction and are disposed parallel to each other.

An accommodation hole for penetrating a partial area of the cell divider may be formed on each of the cell dividers, and the at least one island type connecting member may be accommodated in the accommodation hole.

A thickness of an area of the cell divider where the accommodation hole is not formed may be thinner than an entire thickness of an area of the cell divider where the accommodation hole is formed.

The island type connecting member may include a metal or a conductive resin.

### BRIEF DESCRIPTION OF THE DRAWINGS

A more complete appreciation of the present invention, and many of the attendant advantages thereof, will become readily apparent as the same becomes better understood by reference to the following detailed description when considered in conjunction with the accompanying drawings in which like reference symbols indicate the same or similar components, wherein:

FIG. 1 illustrates a plane structure of a photoelectric conversion module according to an embodiment of the present invention, which is viewed from upward;

FIG. 2 generally illustrates an exploded perspective view of the photoelectric conversion module of FIG. 1;

FIG. 3 illustrates a cross-sectional view taken along a line of FIG. 1;

FIG. 4 illustrates a cross-sectional view taken along a line IV-IV of FIG. 1;

FIG. 5 illustrates an exploded perspective view schematically illustrating a photoelectric conversion module according to another embodiment of the present invention; and

FIG. 6 illustrates a perspective view of a partial structure of FIG. 5, wherein a first electrode including a metal electrode is connected to a second electrode including another metal electrode via an island type connecting member.

### DETAILED DESCRIPTION OF THE EMBODIMENTS

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description. The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. It will be understood that although the terms first and second are used herein to describe various elements, these elements should not be limited by these terms. These terms are only used to distinguish one element from another element.

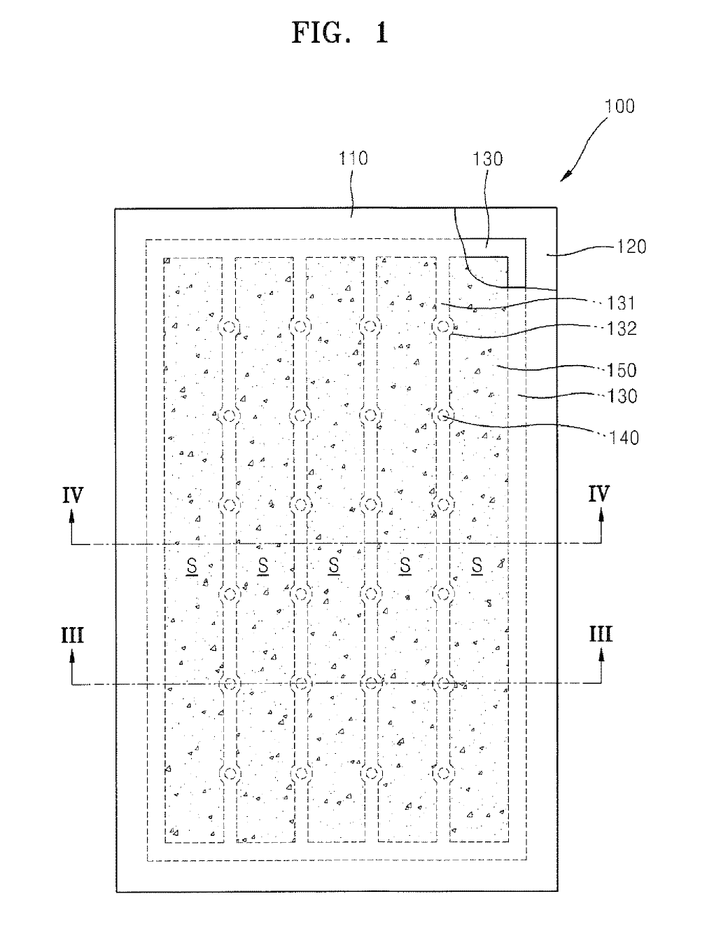

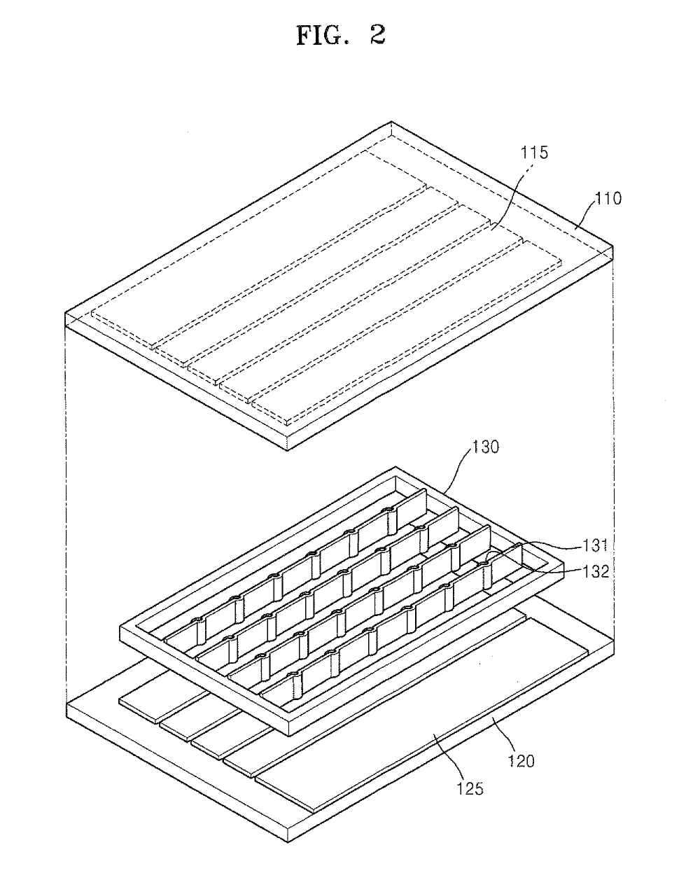

FIG. 1 illustrates a plane structure of a photoelectric conversion module 100 according to an embodiment of the present invention, which is viewed from upward, and FIG. 2 illustrates an exploded perspective view of the photoelectric conversion module 100 of FIG. 1.

The photoelectric conversion module 100 includes at least one photoelectric cell S, which are defined by a sealing member 130. The plurality of photoelectric cells S may be disposed parallel to each other in one direction, and may be modularized by being physically supported between a first substrate 110 and a second substrate 120.

An electrolyte 150 is filled in the photoelectric cell S. The electrolyte 150 is sealed by the sealing member 130 which surrounds the photoelectric cells S overall and is disposed between the neighboring photoelectric cells S. In other words, the sealing member 130 is disposed around the electrolyte 150 to surround the electrolyte 150, thereby preventing the electrolyte 150 from leaking.

Meanwhile, the sealing member 130 includes at least one space for accommodating the photoelectric cell S. When the plurality of photoelectric cells S are included, the space for accommodating the photoelectric cells S are defined by a cell divider 131 disposed between the photoelectric cells S. For example, when the photoelectric cells S are disposed parallel to each other in one direction, a plurality of the cell dividers 131 may be disposed parallel to each other while being spaced apart from each other.

The sealing member 130 includes at least one space for accommodating an island type connecting member 140. The space for accommodating the island type connecting member 140 is defined by an accommodation hole 132 formed to penetrate a partial area of the cell divider 131. For example, when a plurality of the island type connecting member 140 are included, the accommodation holes 132 are spaced apart from each other.

The island type connecting member 140 disposed in the accommodation hole 132 connects one photoelectric cell S to another photoelectric cell S, and the photoelectric cells S are electrically connected via the island type connecting member 140. For example, the island type connecting member 140 electrically connects the photoelectric cells S on each side of the corresponding cell divider 131.

Meanwhile, since the cell divider 131 surrounds the island type connecting member 140, the island type connecting member 140 is protected from the electrolyte 150 included in the photoelectric cell S. Accordingly, a thickness of the cell divider 131 where the accommodation hole 132 is formed may be thicker than a thickness of the cell divider 131 where the accommodation hole 132 is not formed. Also, as shown in FIGS. 1 and 2, an area where the accommodation hole 132 is formed may protrude from the cell divider 131. In FIG. 2, an inner part of the accommodation hole 132 is a hollow cylinder, but a shape of the accommodation hole 132 is not limited thereto. For example, the shape of the accommodation hole 132 may vary, such as a polygonal pillar.

Functional layers 115 and 125 for performing photoelectric conversion are respectively formed on the first and second substrates 110 and 120, as shown in FIG. 2.

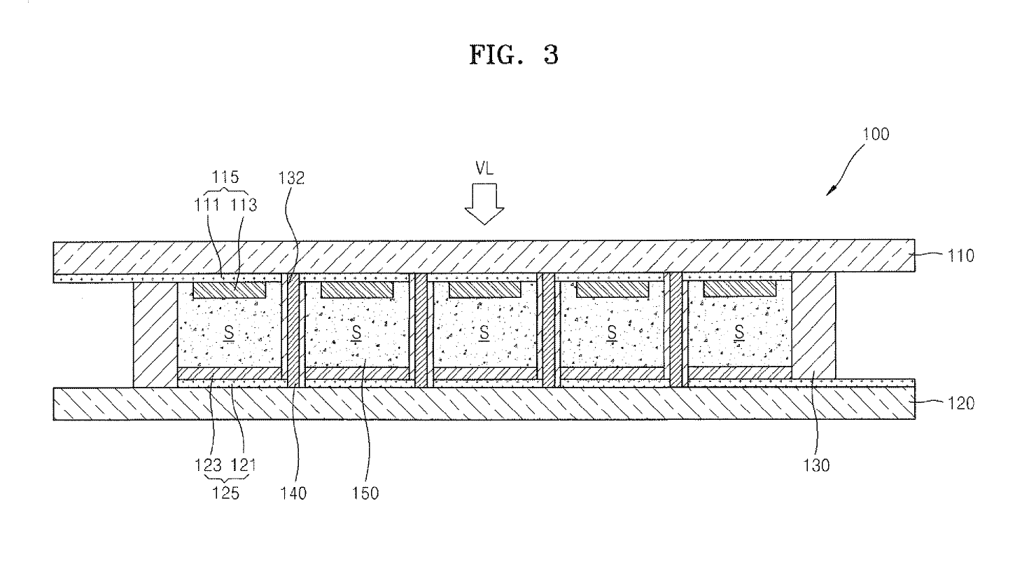

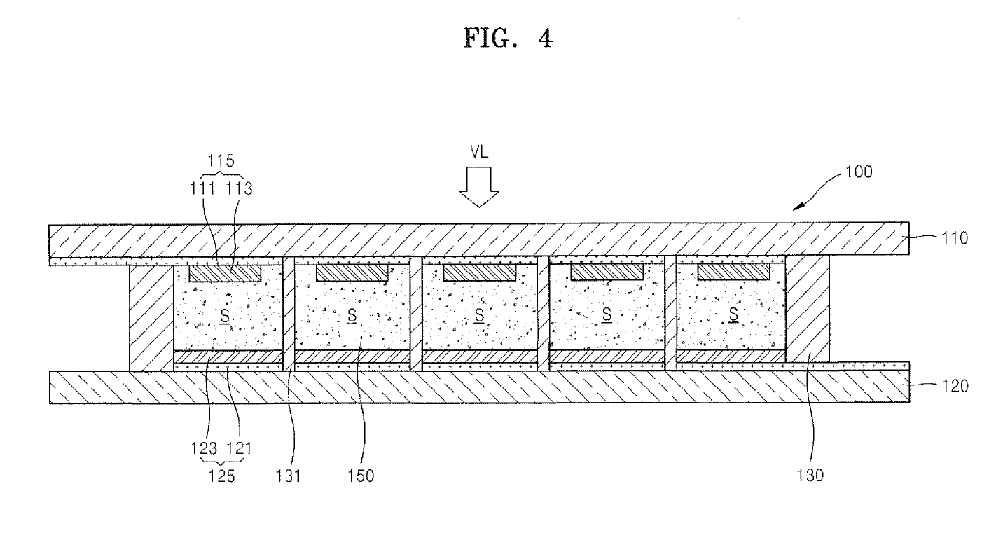

FIG. 3 illustrates a cross-sectional view taken along a line of FIG. 1, and FIG. 4 illustrates a cross-sectional view taken along a line IV-IV of FIG. 1. The photoelectric cells S are connected to each other via the island type connecting members 140, and thus connection points between the neighboring photoelectric cells S are disposed apart from each other. Accordingly, an area where the island type connecting member 140 is included as shown in FIG. 3, and an area where the island type connecting member 140 is not included as shown in FIG. 4 coexist.

Referring to FIGS. 3 and 4, the photoelectric conversion module 100 includes the first and second substrates 110 and 120, which are disposed to face each other, and the sealing member 130 disposed between the first and second substrates 110 and 120. Also, the photoelectric conversion module 100 includes at least one photoelectric cell S defined by the sealing member 130. The functional layers 115 and 125 for performing photoelectric conversion are respectively formed on the first and second substrates 110 and 120. The functional layer of the first substrate 110 includes a photoelectrode 111 and a semiconductor layer 113, and the functional layer 125 of the second substrate 120 includes a counter electrode 121 and a catalyst layer 123.

The first and second substrates 110 and 120 may have a rough rectangular shape. The first substrate 110 is disposed on the top of the photoelectric conversion module 100 and the second substrate 120 is disposed on the bottom of the photoelectric conversion module 100.

The first substrate 110 may be a light-receiving substrate, and may be formed of a transparent material having high light transparency. The first substrate 110 may be formed of, for example, glass or a resin film. Since the resin film is flexible, the resin film may be used when the first substrate 110 needs to be flexible.

The second substrate 120 is a counter substrate, and is disposed to face the first substrate 110 constituting the light-receiving substrate. The counter substrate may not specifically be transparent, but may be formed of a transparent material to receive a light VL from both sides so as to increase photoelectric conversion efficiency. The counter substrate may be formed of the same material as the light-receiving substrate. For example, when the photoelectric conversion module 100 is used as for a building integrated photovoltaic (BIPV) purpose that is installed in a structure such as a windowsill, the first and second substrates 110 and 120 may be formed of a transparent material so as not to block the light VL incident into a room.

The first and second substrates 110 and 120 cohere with each other with a predetermined gap in which the sealing member 130 is disposed. The photoelectrode 111 and the counter electrode 121 are respectively formed on the first substrate 110 and the second substrate 120. The semiconductor layer 113, on which a photosensitive dye that is excited by the light VL is adsorbed, is formed on the photoelectrode 111, and the electrolyte 150 is disposed between the photoelectrode 111/semiconductor layer 113 and the catalyst layer 123.

The photoelectrode 111 operates as a negative electrode of the photoelectric conversion module 100, and provides a current path by collecting electrons generated according to photoelectric conversion. The light VL incident through the photoelectrode 111 operates as an excitation source of the photosensitive dye adsorbed on the semiconductor layer 113. The photoelectrode 111 may be formed of a transparent conducting oxide (TCO), such as an indium tin oxide (ITO), fluorine tin oxide (FTO), or antimony tin oxide (ATO), which have electric conductivity and light transparency.

The semiconductor layer 113 may be formed by using a semiconductor material used to form a general photoelectric conversion module. Alternatively the semiconductor layer 113 may be formed of a metal oxide. Examples of the metal oxide include cadmium (Cd), zinc (Zn), indium (In), lead (Pb), molybdenum (Mo), tungsten (w width), antimony (Sb), titanium (Ti), silver (Ag), manganese (Mn), tin (Sn), zirconium (Zr), strontium (Sr), gallium (Ga), silicon (Si), and chrome (Cr).

The photoelectric conversion efficiency may be increased by adsorbing the photosensitive dye to the semiconductor layer 113. For example, the semiconductor layer 113 may be formed by coating a paste, in which semiconductor particles having a particle diameter from about 5 nm to about 1000 nm are dispersed, on first substrate 110 including photoelectrode 111, and then applying a predetermined heat or pressure to the first substrate 110.

The photosensitive dye adsorbed to the semiconductor layer 113 absorbs the light VL incident through the first substrate 110, and electrons of the photosensitive dye are excited from a ground state. The excited electrons move to a conduction band of the semiconductor layer 113 through electric combination of the photosensitive dye and the semiconductor layer 113, and then reach the photoelectrode 111 through the semiconductor layer 113. Next, the excited electrons are externally extracted out of the photoelectric conversion module 100 through the photoelectrode 111 thereby forming a driving current for driving an external circuit (not shown).

The photosensitive dye is absorbed in a visible ray band, and may be configured as molecules for quickly transferring the electrons from a light excitation state to the semiconductor layer 113. The photosensitive dye may be in a liquid state, a semisolid gel state or a solid state. For example, a ruthenium-based photosensitive dye may be used.

A redox electrolyte including a pair of an oxidized material and a reduced material may be used as the electrolyte 150 filled in the photoelectric cell S. Any one of a solid electrolyte, a gel electrolyte, and a liquid electrolyte may be used as the electrolyte 150.

The counter electrode 121 operates as a positive electrode of the photoelectric conversion module 100. The photosensitive dye adsorbed to the semiconductor layer 113 is excited by absorbing the light VL, and the excited electrons are externally extracted through the photoelectrode 111. Meanwhile, the photosensitive dye, which loses the electrons, is then reduced as it receives electrons provided by oxidation of the electrolyte 150. The oxidized electrolyte 150 is reduced as it receives electrons that have reached the counter electrode 121 through the external circuit, thereby completing the photoelectric conversion.

Similar to the photoelectrode 111, the counter electrode 121 may be formed of a transparent conducting oxide (TCO), such as an indium tin oxide (ITO), fluorine tin oxide (FTO), or antimony tin oxide (ATO), which has electric conductivity and light transparency.

The catalyst layer 123 may be formed on the counter electrode 121. The catalyst layer 123 may be formed of a material having a reduction catalyst function providing electrons. The catalyst layer 123 may be formed of, for example, a metal such as platinum (Pt), gold (Au), silver (Ag), or aluminum (Al), a metal oxide such as a tin oxide, or a carbon-based material such as graphite.

The plurality of photoelectric cells S may be connected in series via at least one connection point. The island type connecting member 140 forms the connection point by being disposed in the accommodation hole 132 formed in the cell divider 131. The island type connecting member 140 extends so that upper side portion of the island type connecting member 140 contacts with end portion of the photoelectrode 111 of a first cell S, and lower side portion of the island type connecting member 140 contacts with end portion of the catalyst layer 123 of a second cell S neighboring the first cell S. Thereby, the island type connecting member 140 connects the cells S in series.

A metal such as silver (Ag) or nickel (Ni) having excellent conductivity, or a conductive resin may be used as a conductive material for island type connecting member 140. An example of the conductive resin includes a room temperature hardening conductive resin. Meanwhile, since the island type connecting member 140 is disposed in the accommodation hole 132 formed in the cell divider 131, the island type connecting member 140 is protected from the electrolyte 150. A number of the island type connecting members 140 may be determined considering a size of the photoelectric conversion module 100 and efficiency according to the size.

Since the photoelectric cells S are connected to each other via the island type connecting member 140, the cell divider 131 includes an area where the accommodation hole 132 for accommodating the island type connecting member 140 is formed (FIG. 3), and the area where the accommodation hole 132 is not formed (FIG. 4). Here, the area where the accommodation hole 132 is formed is relatively thicker than the area where the accommodation hole 132 is not formed, since the cell divider 131 surrounds the island type connecting member 140 so as to protect the island type connecting member 140 from the electrolyte 150.

On the other hand, the thickness of the cell divider 131 may be thin since the area where the accommodation hole 132 is not formed (FIG. 4) only has to define the neighboring photoelectric cells S. Since the thickness of the cell divider 131 is thin, a dead area (where the cell divider 131 is disposed adjacent the electrodes) not capable of absorbing the light VL decreases and an active area capable of absorbing the light VL relatively increases. Thus, a current amount increases, thereby increasing an output of the photoelectric conversion module 100.

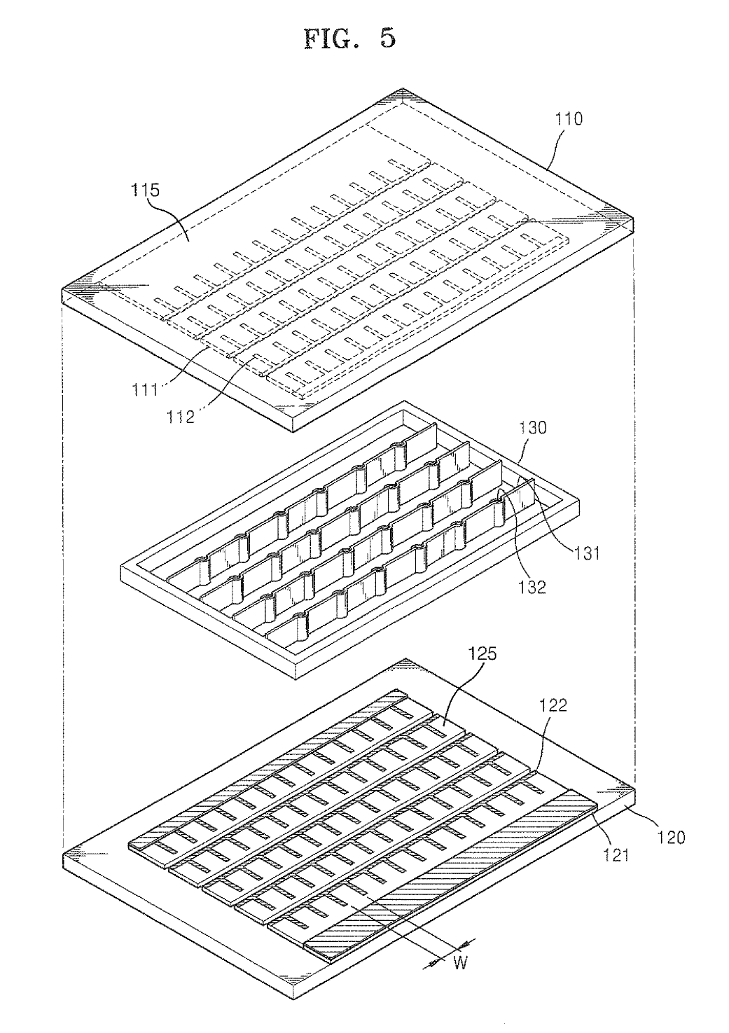

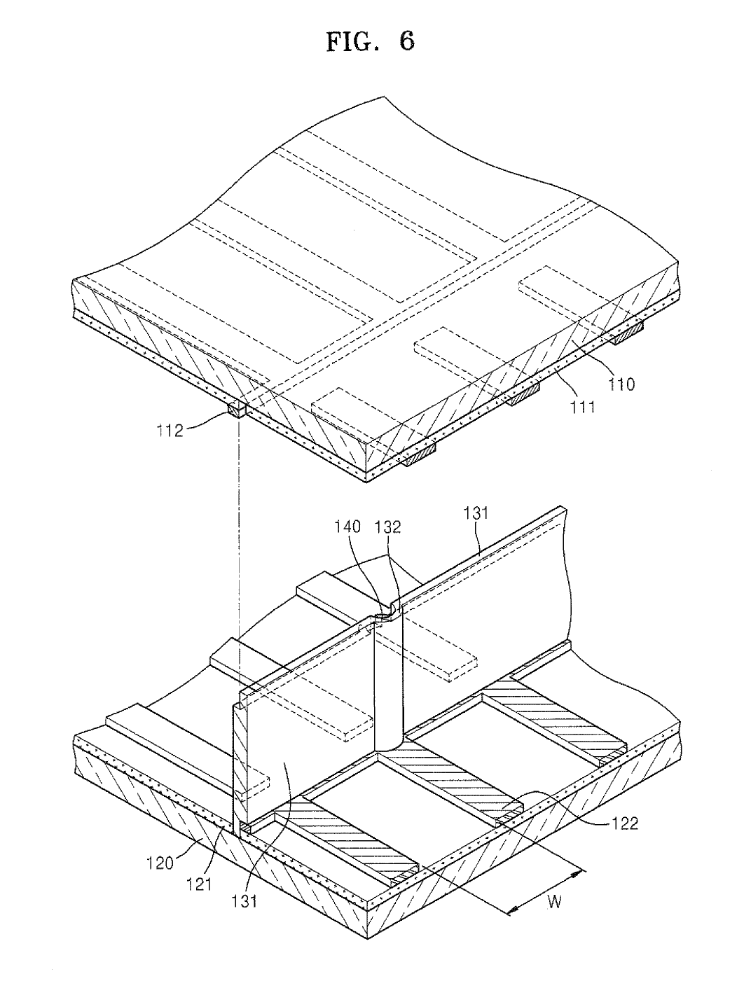

FIG. 5 illustrates an exploded perspective view schematically illustrating a photoelectric conversion module according to another embodiment of the present invention, and FIG. 6 illustrates a perspective view of a partial structure of the photoelectric conversion module, in which the photoelectric cells S are connected in series by the island type connecting member 140 forming a contacting point.

Referring to FIG. 5, the photoelectric conversion module according to this embodiment of the present invention includes the first substrate 110 and the second substrate 120, which are disposed to face each other, and the sealing member 130 disposed between the first and second substrates 110 and 120. Also, the photoelectric conversion module includes at least one photoelectric cell S defined by the sealing member 130. The functional layers 115 and 125 for performing photoelectric conversion are respectively formed on the first substrate 110 and the second substrate 120. The functional layer 115 of the first substrate 110 includes the photoelectrode 111, the metal electrodes 112, and the semiconductor layer (not shown), and the functional layer 125 of the second substrate 120 includes the counter electrode 121, the metal electrodes 122 and the catalyst layer (not shown).

The photoelectric conversion module according to the this embodiment is different from the photoelectric conversion module 100 according to the previous embodiment, in that metal electrodes 112 and 122 are respectively formed on the photoelectrode 111 and the counter electrode 121. The semiconductor layer (not shown) may be formed on the metal electrode 112 and the photoelectrode 111, and catalyst layer (not shown) may be formed on the metal electrode 122 and the counter electrode 121. The metal electrodes 112 and 122 may be formed of a material, such as Ag, Au, or Al, having excellent electric conductivity. The metal electrodes 112 and 122 are used to decrease electric resistance of the photoelectrode 111 and the counter electrode 121, and may have a stripe or mesh pattern. In FIGS. 5 and 6, the metal electrodes 112 and 122 have a stripe pattern.

The photoelectrode 111, the counter electrode 121, and the metal electrodes 112 and 122 are electrically connected via the island type connecting member 140. In FIG. 6, the photoelectrode 111 and the metal electrode 112 formed on the first substrate 110 are connected to the metal electrode 122 and the counter electrode 121 formed on the second substrate 120 via the island type connecting member 140. Here, if a width w of a pattern of the metal electrodes 112 and 122 is too dense, electric resistance may be decreased but a dead area increases, and thus an output is deteriorated. On the other hand, if the width W is too wide, the electric resistance increases, and thus the output is deteriorated. Accordingly, the width W may be from about 5 mm to about 15 mm, and in detail, may be about 10 mm.

The metal electrodes 112 and 122 may be protected from an electrolyte accommodated in the photoelectric cell S by being covered by a protective layer (not shown). The protective layer may be formed of a glass frit-based or resin-based material having insulating properties.

The photoelectric conversion module according to the current embodiment includes the island type connecting member 140, and thus the active area capable of absorbing the light VL is increased. Accordingly, an output of the photoelectric conversion module may be increased. Moreover, by further including the metal electrodes 112 and 122 having a grid interval from about 5 mm to about 15 mm, the output increases more.

A number of the island type connecting members 140 may be determined while considering a size of the photoelectric conversion module. For example, if a length of the photoelectric conversion module is about 75 mm, the number of island type connecting members 140 disposed between neighboring photoelectric cells S may be from about 1 to about 10, in detail, about 6.

As described above, according to the one or more of the above embodiments of the present invention, photoelectric cells are connected to each other by using at least one island type connecting member as the connection point, and thus an aperture ratio is increased, thereby increasing photoelectric conversion efficiency.

Also, by point-connecting the photoelectric cells using the island type connecting member and employing a simple structure, manufacturing costs may be reduced and productivity may be increased.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A photoelectric conversion module comprising:
a first substrate and a second substrate, which are disposed to face each other;
a sealing member disposed between the first and second substrates, and defining a plurality of photoelectric cells performing photoelectric conversion; and
an island type connecting member connecting neighboring photoelectric cells from among the plurality of photoelectric cells.

2. The photoelectric conversion module of claim 1, wherein each of the plurality of photoelectric cells comprises a first electrode and a second electrode having different polarities, and
the island type connecting member extends to contact the first electrode of a first neighboring photoelectric cell and the second electrode of a second neighboring photoelectric cell.

3. The photoelectric conversion module of claim 2, wherein at least one of the first and second electrodes comprises a metal electrode having a stripe pattern.

4. The photoelectric conversion module of claim 3, wherein a width of the stripe pattern of the metal electrode is from about 5 mm to about 15 mm.

5. The photoelectric conversion module of claim 1, wherein the sealing member comprises:
a cell divider dividing the plurality of photoelectric cells; and
an accommodation hole accommodating the island type connecting member.

6. The photoelectric conversion module of claim 5, wherein the accommodation hole formed to penetrate a partial area of the cell divider.

7. The photoelectric conversion module of claim 6, wherein a thickness of the cell divider where the accommodation hole is not formed is thinner than a thickness of the cell divider where the accommodation hole is formed.

8. The photoelectric conversion module of claim 1, wherein the island connecting member is disposed between the neighboring photoelectric cells.

9. The photoelectric conversion module of claim 8, wherein a plurality of the island type connecting members are disposed apart from each other.

10. The photoelectric conversion module of claim 1, wherein the island type connecting member comprises a metal or a conductive resin.

11. The photoelectric conversion module of claim 1, wherein the plurality of photoelectric cells extend along one side unit of the first and second substrates and are disposed parallel to each other.

12. A photoelectric conversion module comprising:
a plurality of photoelectric cells performing photoelectric conversion and disposed between a first substrate and a second substrate facing the first substrate; and
at least one island type connecting member disposed between neighboring photoelectric cells from among the plurality of photoelectric cells and connecting the neighboring photoelectric cells.

13. The photoelectric conversion module of claim 12, wherein each of the plurality of photoelectric cells comprises:
a first electrode and a second electrode respectively formed on the first substrate and the second substrate;
a semiconductor layer formed on the first electrode; and
an electrolyte disposed between the semiconductor layer and the second electrode.

14. The photoelectric conversion module of claim 13, wherein the at least one island type connecting member extends to connect the first electrode of a first one of the neighboring photoelectric cells and the second electrode of a second one of the neighboring photoelectric cells.

15. The photoelectric conversion module of claim 13, wherein at least one of the first and second electrodes comprises a metal electrode having a stripe pattern.

16. The photoelectric conversion module of claim 15, wherein a width of the stripe pattern of the metal electrode is from about 5 mm to about 15 mm.

17. The photoelectric conversion module of claim 12, wherein the plurality of photoelectric cells are defined by a sealing member comprising cell dividers that extend in one direction and are disposed parallel to each other.

18. The photoelectric conversion module of claim 17, wherein an accommodation hole for penetrating a partial area of the cell divider is formed through each of the cell dividers, and the at least one island type connecting member is accommodated in the accommodation hole.

19. The photoelectric conversion module of claim 18, wherein a thickness of an area of the cell divider where the accommodation hole is not formed is thinner than an entire thickness of an area of the cell divider where the accommodation hole is formed.

20. The photoelectric conversion module of claim 12, wherein the island type connecting member comprises a metal or a conductive resin.
